(19) United States
(12) Patent Application Publication
(10) Pub. No.: US 2011/0012236 A1
(43) Pub. Date: Jan. 20, 2011

(54) EVALUATION OF AN UNDERCUT OF DEEP TRENCH STRUCTURES IN SOI WAFERS

(76) Inventors: Karlheinz Freywald, Erfurt (DE); Gisbert Hoelzer, Erfurt (DE)

Correspondence Address: STEVENS & SHOWALTER LLP, 7019 CORPORATE WAY, DAYTON, OH, 45459-4238, US

(21) Appl. No.: 12/161,669

(22) PCT Filed: Jan. 19, 2007
(86) PCT No.: PCT/EP07/50572

§ 371 Date: Sep. 17, 2010

(30) Foreign Application Priority Data
Jan. 20, 2006 (DE) 10 2006 002 753.1

(51) Int. Cl. H01L 29/06; H01L 21/66

(52) U.S. Cl. 257/618; 438/14; 257/E21.529; 257/E29.005

(57) ABSTRACT

A technique is provided which enables quantitative evaluation of an undercutting of deep trench structures in semiconductor wafers and, in particular, SOI wafers, by means of electrical or optical measuring. A specific control structure (100) having a defined ridge width is used which can be routinely measured in the course of the production process. The control structure comprises two adjacent trenches (5) each which are separated by a ridge having a defined ridge width. By undercutting (U) the adjacent trenches, the regions of undercutting of adjacent trenches may intersect each other starting from a specific minimum ridge width which results in a detachment of the ridge from the bottom making the ridge moveable. Mobility is determined by thermal deflection of the ridge. Arranging a plurality of control structures having various ridge widths enables determination of a quantitative amount of the undercutting.

The invention relates to a method and an arrangement for evaluation an undercutting of deep trench structures in substrates, which are suitable for the production of micro-structure components, such as SOI wafers.

The control methods employed so far do not meet the requirements made to a simple and safe routine measurement within the scope of process control in the production process. In practice, cross-sections are often produced, the geometrical dimensions of which are subsequently measured by means of a scanning electron microscope.

These cross-sections are either produced by means of ion beam etching and refilling (very high effort with deep trenches) or a rupture is created wherein the wafer to be examined is destroyed.

Conventional optical methods for evaluation of undercuts require transparency of at least one layer necessary for evaluation or require a window-like arrangement. Such a control structure is described in WO-A 00/17095. This methodology cannot be applied to deep trench structures and does not correspond to the problem to be solved.

In further patents, methods for producing deep trench structures are described which, however, do not include any statement as to evaluation thereof or determination of an undercutting, e.g. U.S. Pat. No. 6,770,506; U.S. Pat. No. 6,887,391 and U.S. Pat. No. 6,712,983.

U.S. Pat. No. 6,211,598 shows a thermally excited actuator which is neither intended for controlling an undercutting and nor suitable for this purpose and which enables movement in the plane. The finger of the actuator is suspended on one side.

DE-C 100 15 598 describes a micro relay which is thermally excited. Excitation takes place both, in parallel with the surface and perpendicular to the surface. However, this functional principle is not intended for controlling an undercutting.

In U.S. Pat. No. 5,909,078, a thermally excited arched actuator having a two-sided suspension for driving a micro valve is described. There is no hint as to any use thereof for evaluating an undercutting of trench structures in this document.

In U.S. Pat. No. 6,030,903, for determining an undercutting of structures located in a surface layer, a pattern of etch-resistant lines of various widths which are equally spaced from each other is applied to the surface layer by etching a hidden layer disposed on a substrate below the surface layer and gauging the undercutting based on the removed lines, starting with the narrowest line. This procedure is most complex with regard to area and evaluation of results and includes the risk of generation of defects on the process wafers (e.g. contamination).

In an apparatus for measuring elastic micro stresses known from U.S. Pat. No. 6,015,599, small bars of polysilicon are put under stress by heating, wherein heating is performed via a ring surrounding the structure, which ring is heated by electric resistance heating. This is not a method for measuring the amount of undercutting in trench etching.

In application WO-A 2005/084394 A2, a method is described in connection with MEMS structures by means of which thin ridges, which have to be freestanding in order to fulfill their function, but are adhered to the surface of the substrate by adhesion forces, are released by a laser pulse on the backside of the substrate. The radiation pulse causes a short-term temperature difference between substrate and thin ridge (heating of the substrate) which results in a release of the thin ridge by means of generated elastic stresses.

The invention is based on the object of providing an efficient, non-destructive method which is substantially free of subjective influence and a corresponding arrangement for routinely evaluating an undercutting of deep trench structures in substrates which may be used in process control. A preferred purpose of the invention is to improve process control and stability of the etching process in insulation trench etching of SOI wafers for increasing the output.

The object is achieved by the independent claims.

According to the invention, this object is achieved by providing methods and arrangements enabling a non-destructive and preferably electrical control of semiconductor structures wherein known or standard test systems may be employed in an advantageous manner. For this purpose, the material loss caused by undercutting a specified ridge is evaluated or rendered evaluable in view of a change in electrical behavior and/or heat conducting behavior and/or mechanical behavior. Mobility is evaluable upon occurrence of stresses. This may be accomplished on the basis of optical and/or electrical measuring methods. In this way, process control and stability of the etching process in insulation trench etching of substrates for the production of micro-structure components and, in particular, of SOI wafers may be improved for increasing the output.

According to one aspect, the object is achieved by a method for evaluating an undercutting of deep trench structures in a semiconductor wafer using a control structure created on the semiconductor wafer. The control structure is configured such that a ridge having a defined ridge width is formed between two adjacent trenches as a result of trench etching, which ridge is undermined when undercuts merge into each other. The ridge is heated after trench etching, whereby the undermined ridge is caused to move in a clearly recognizable manner as compared to a non-undermined ridge due to expansion, which movement is then registered and serves as a criterion of ridge mobility for evaluating the amount of undercutting (claim 1).

Due to this procedure, the ridge is undercut during the etching process, wherein the design dimensions may be chosen such that at least a partial undermining is created as a result of the two-sided undercutting so that regions of the ridge below the ridge surface are open between the adjacent trenches (claim 5). Because of the material reduction caused by etching and the undermining associated therewith, inter alia, thermal coupling of the ridge material to the remainder of the substrate is reduced so that high temperatures may be generated locally in the ridge material in a highly efficient manner, which high temperatures then lead to corresponding stresses. The mechanical connection of the ridge to the surrounding material is also reduced by the undermining so that higher mobility is achieved as well so that, due to thermal stress, a movement can be caused which is well observable and may be used for evaluating the amount of undermining and thus the amount of undercutting.

In an advantageous embodiment, heating and registration of ridge mobility are performed electrically. In this case, established measuring probes may be used for generating thermal stresses and for detecting the resultant movement.

In a further advantageous embodiment, heating is performed by radiation and ridge mobility is registered electrically. A corresponding process sequence offers a high degree of reliability regarding performance and significance of the detected mobility, as the heating may take place in a non-contact manner and thus without having a strong influence with regard to effect on adjacent component areas, while the caused movement may be determined by electrical measurement with very low currents, such as by detecting contact of the ridge with an opposite trench wall.

In yet a further advantageous embodiment, heating is performed by radiation and ridge mobility is registered optically. Thus, a completely non-contact measuring procedure is enabled which results in a low wafer contamination and thus a low influence on the subsequent production process.

In yet a further advantageous embodiment, heating is performed electrically and ridge mobility is registered optically. Thus, a well-controllable local heating of the ridge due to electric current flow is accomplished, while detection of movement may be performed by any suitable optical method, for example, microscopically.

In yet a further advantageous embodiment, the ridge is deflected until it contacts a trench wall whereby electrical contact is made which is then registered. Thus, a highly reliable detection of the deformation of the ridge caused by heating is achieved as the ridge fulfils the function of a switch.

In yet a further advantageous embodiment, control structures having variously defined stepped ridge widths are disposed on the semiconductor wafer and the amount of undercutting is determined after trench etching on the basis of registration of ridge mobility and knowledge of the respective defined ridge width. Thus, a high degree of sensitivity of the method may be accomplished already during construction by defining the various design widths of the ridges. The number of the various ridge widths and the stepping thereof may be chosen such that process variations occurring in the trench etching process may be covered by a desired measuring resolution. Consequently, the same layouts of the control structures may also be efficiently employed when changing the trench etching process recipe.

The radiation for heating the ridge may be laser radiation so that known devices may be employed. In other cases, flash lamps may be used.

In yet a further advantageous embodiment, the adjacent trenches serving the purpose of forming the ridge are configured such that a defined preferred lateral direction for deflection of the ridge is obtained upon heating of the ridge. Thus, efficient detection is accomplished since it is ensured that a defined and thus well recognizable movement takes place upon expansion of the ridge material. For example, a corresponding basic shape of the ridge may be chosen in form of a curvature which results in a lateral movement determined by the curvature upon expansion due to heating.

In yet a further advantageous embodiment, the semiconductor wafer represents a SOI structure having a hidden insulating layer and a semiconductor layer formed thereon. In this case, electrical measurements may be conducted in a particularly efficient manner, since the trench structure usually causes electrical insulation of the ridge and thus enables purposeful utilization of the electrical properties of the ridge.

In a further aspect of the invention, a method for evaluating an undercutting of deep trench structures in substrates suitable for the production of micro-structure components is provided. The method comprises producing a ridge having a defined ridge width between two adjacent trenches by means of trench etching, and generating a current flow in the ridge. Furthermore, the amount of undercutting of the ridge occurring during trench etching in a deeper region of the adjacent trenches is assessed on the basis of the generated current flow and the material loss of the ridge determined by the amount of undercutting.

By generating a current flow, efficient detection of the material loss caused by etching may thus be achieved, i.e. the degree of undercutting and, if necessary, the degree of undermining may be determined by determining, for example, the resistance or conductivity or a parameter correlated with these characteristics.

In this case, quantitative measurements may be obtained even if the degree of undercutting has not yet resulted in a significant change of mobility of the ridge, wherein low currents may be used for measuring so that a change in electrical behavior of the semiconductor material caused by measuring is low.

In yet a further advantageous embodiment, the current flow is generated in a suitable level for heating the ridge, whereby the undermined ridge is caused to move in a clearly recognizable manner as compared to a non-undermined ridge due to expansion, which movement is registered and serves as a criterion of ridge mobility for assessing the amount of undercutting. Thus, in addition or as an alternative to determination of conductivity, the reduced thermal and mechanical coupling of the at least partially undermined ridge may be utilized, wherein optical and/or electrical methods may be used for detecting the movement, as also described above.

According to a further aspect, an arrangement for evaluating an undercutting of deep trench structures in semiconductor wafers is provided. The arrangement comprises a component area for producing micro-structure components, which area is defined by a trench structure having a defined trench width. Furthermore, a first control structure is provided having a structure different from that of the micro-structure components and a ridge which is formed by two adjacent trenches having a defined width and which is partially open between the adjacent trenches.

This arrangement provides the means required for performing the measuring methods described above and below, wherein in a wafer, comprising or intended to comprise component structures in the component area, the control structure enables efficient “inline” determination of the quality of the trench etching process in the component area. The measuring results obtained by the control structure may also be used for controlling the etching process of wafers to be processed subsequently due to their rapid availability and high statistical relevance.

In yet a further advantageous embodiment, the ridge is fixed at both ends each and comprises a contact surface to be contacted by an external test probe. The contact surface, which serves as a touching surface for a probe and has a size suitable for this purpose, also serves the purpose of fixing the ridge, as a complete undermining of the contact surface is avoided by the larger lateral dimensions of the contact surface as compared to the ridge width so that the contact surface is mechanically firmly connected to the substrate.

In yet a further advantageous embodiment, a further contact surface formed in a semiconductor layer is provided which is electrically insulated from the contact surfaces of the ridge. Thus, mechanical contact of the ridge with the semiconductor layer may be detected electrically by means of the further contact surface.

In yet a further advantageous embodiment, the ridge has a curvature in order to define a preferred lateral direction upon thermal expansion of the ridge. By defining a preferred lateral direction, accuracy of detection is enhanced.

In yet a further advantageous embodiment, one or more further control structures having a ridge are provided, wherein the ridge of the one or more further control structures is formed by adjacent trenches having a defined trench width and has a ridge width differing from that of the ridge of the first control structure. Thus, a very precise quantitative analysis of the undercutting and thus of the etching parameters may be performed, wherein a great variety of different ridge widths may also cover a wide range of etching parameters, if necessary.

In yet a further advantageous embodiment, the adjacent trenches forming the ridge of the first control structure extend in such a way that the first control structure is fully enclosed. Thus, a decoupling, for example in an electrical manner, from the substrate may be achieved to the greatest possible extent whereby electric measurements may be performed more efficiently. This holds true, in particular, if the adjacent trenches extend up to a hidden insulation layer when considering a SOI arrangement.

In a further aspect of the invention, an arrangement for evaluating an undercutting of deep trench structures in SOI wafers is provided. The arrangement comprises a component area, which is defined by trenches having a defined width, and a plurality of control structures located outside the component area, each comprising one respective ridge formed by adjacent trenches having a defined width, wherein the ridge widths at the surface are provided with values graded in a defined manner so that the ridges have various amounts of undercutting due to trench etching and thus various amounts of lateral mobility. Thus, etching parameters may be precisely determined even over a wide range of process variations. In particular, if each ridge has a curvature so that a preferred lateral direction is defined upon thermal expansion of the ridges, precision of measurement of each control structure is accomplished due to the defined preferred direction.

In yet a further advantageous embodiment, the curvature is characterized by a radius of curvature which is greater than a length of the associated ridge. Thus, the ridge may have a substantially “straight” form, since the curvature only needs to be very low in order to obtain a defined preferred direction. Thus, the adjacent trenches may be provided almost “in parallel” so that geometrical ratios may be created along the ridge, which are very similar to the conditions in the component area.

In a further aspect, an arrangement in form of a control structure for evaluating an undercutting of deep trench structures in SOI wafers is provided. The arrangement is configured such that a ridge having a defined ridge width is formed between two adjacent trenches extending substantially in parallel with each other in a portion of the arrangement as a result of trench etching, which ridge is undermined when undercuts merge into each other and regions are formed in two portions adjacent to the ends of the ridge which are not completely undermined during etching, wherein the trench, in form of a closed trench, encloses all three portions of the control structure, and wherein contact points are provided in non-undermined portions at the ends of the ridge and in the adjacent non-etched semiconductor area for supplying electrical current for electric heating of the ridge and for measuring deflection thereof due to heating.

The present invention enables evaluation of an undercutting of deep trench structures in semiconductor substrates, in particular in SOI wafers, in the semiconductor production process by use of conventional test systems, wherein systems detecting optical and/or electric values are employed. The measuring values are thus available relatively quickly and without great effort so that efficient process control may be obtained. For example, inter alia, undercuts of deep trench structures in SOI wafers may be determined electrically and/or optically with regard to quantity in a finely graded manner.

This provides the advantage that evaluation of an undercutting of deep trench structures in SOI wafers in the semiconductor production process is possible by use of conventional test systems detecting electric values. The improvement, inter alia, resides in the fact that undercuts of deep trench structures in SOI wafers may be determined electrically with regard to quantity and in a finely graded manner.

The invention is explained and supplemented by means of exemplary embodiments, wherein it is pointed out that the following illustration is a description of preferred examples of the invention, in which:

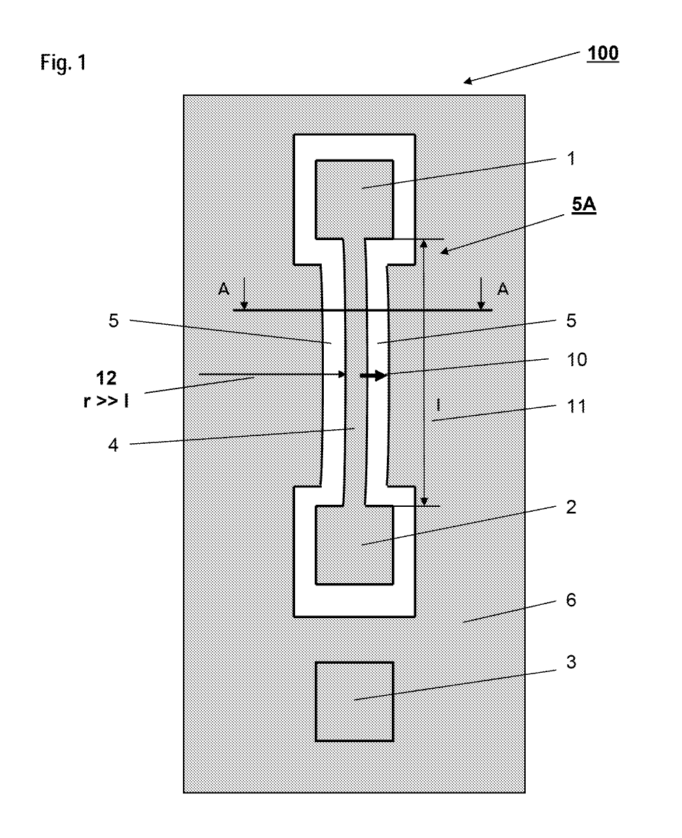

FIG. 1 shows a schematic illustration of the layout of a control structure comprising a ridge for thermo-electric control having a closed trench structure;

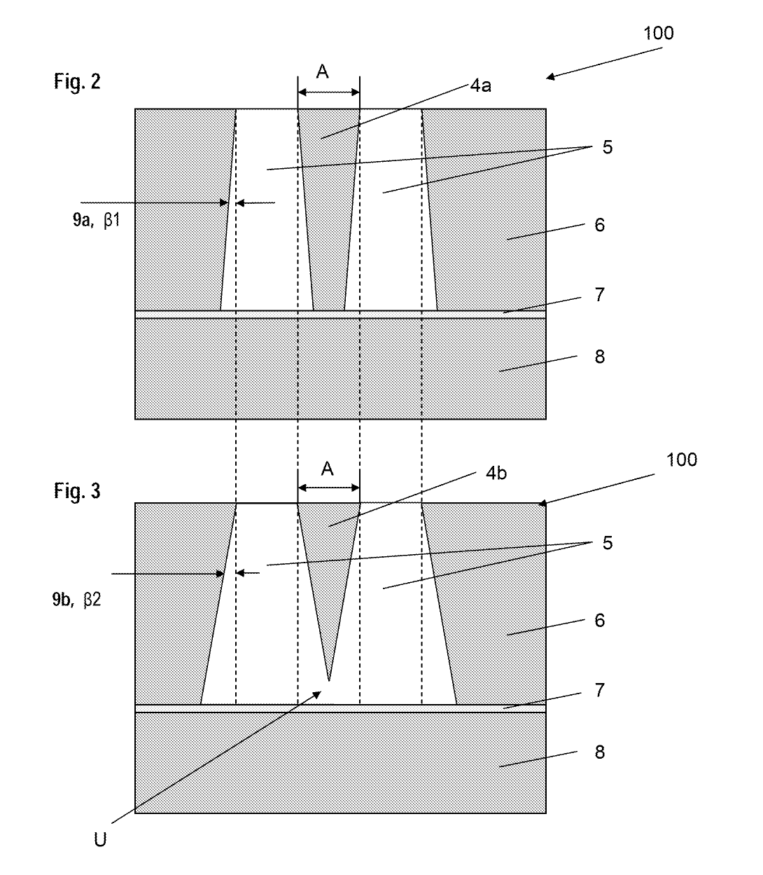

FIG. 2 shows a schematic illustration of cross-section A-A of the control structure of FIG. 1 having a lesser undercutting (angle β1), wherein the undercut regions at the bottom of the trench do not merge into each other;

FIG. 3 shows a schematic illustration of cross-section A-A of the control structure of FIG. 1 having a greater undercutting (angle β2) so that the undercut regions at the bottom of the trench merge into each other and thus form an undermining of the ridge;

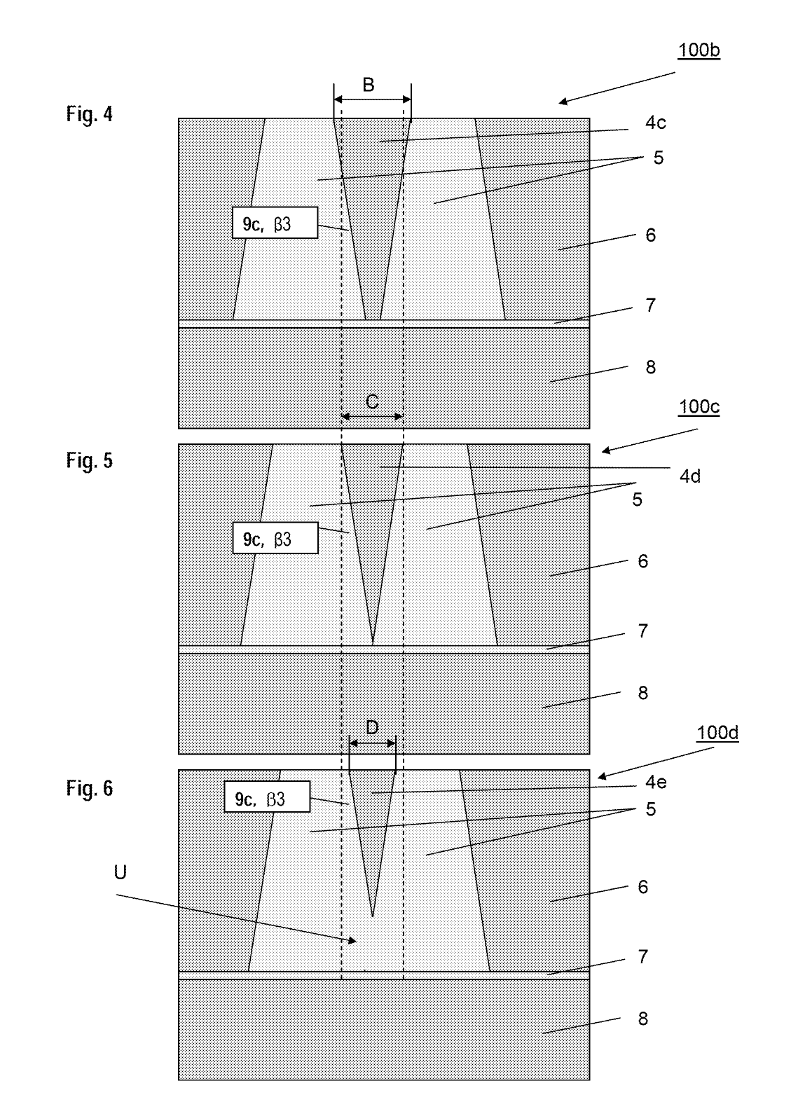

FIG. 4 shows a schematic illustration of cross-section A-A of a control structure similar to that of FIG. 1 having a defined ridge width B, wherein the undercut regions at the bottom of the trench do not merge into each other;

FIG. 5 shows a schematic illustration of cross-section A-A of a control structure similar to that of FIG. 4 having a reduced ridge width C as compared to FIG. 4 after the same etching step as in FIG. 4 (constant angle of undercutting: angle β3), wherein the undercut regions at the bottom of the trench just contact each other;

FIG. 6 shows a schematic illustration of cross-section A-A of a control structure similar to that of FIG. 4 having a reduced ridge width D as compared to FIG. 5 after the same etching step as in FIGS. 4 and 5 (constant angle of undercutting: angle β3), wherein the undercut regions at the bottom of the trench merge into each other and thus form a partial undermining of the ridge.

FIG. 1 shows a plan view of a portion of a substrate in form of a semiconductor layer 6, which may be provided in form of silicon, for the production of micro-structure components. In one embodiment, the wafer is provided in form of a SOI wafer, as is explained in greater detail below. Layer 6, which is also referred to as active layer, comprises a component area (not shown) in which corresponding components or performs thereof are produced or are to be produced.

In layer 6, a control structure 100 is formed which is completely enclosed by a trench structure 5A in the embodiment shown. The trench structure 5A comprises two adjacent trenches 5 having a defined width which is to be understood as the width at the surface of layer 6. The width of the trenches 5 may correspond to the design width of trenches in the component area in order to create similar etching conditions as in the component area. However, other design widths may also be used for the trenches 5, if necessary. The trenches 5 are almost concentric, if a ridge 4 defined by the trenches 5 has a slight curvature which is characterized by the radius of curvature 12 (radius r). In the embodiment shown, the radius of curvature 12 is much greater than the length 11 (“I” as a small L) of the ridge 4. Such a configuration of the trench geometry may also be referred to as trenches extending substantially in parallel with each other in the following, even if the trenches 5 and thus the ridge 4 are not perfectly straight. In other embodiments, the ridge 4 may be formed substantially straight, if definition of a preferred lateral direction, which is indicated by 10 herein and predetermined by the curvature 12, is not required.

Moreover, the control structure 100 comprises a first contact surface 1 and a second contact surface 2 to which the ridge 4 is respectively fixed. Furthermore, a third contact surface 3 is provided in layer 6 outside the region enclosed by the trench structure 5A in the embodiment shown. The three contact surfaces 1, 2, 3 serve the purpose of applying contact tips thereto for electric heating and/or contact measurement and/or measurement of electrical conductivity of the ridge 4.

FIG. 2 shows a section along line A-A of FIG. 1, wherein the control structure 100 is shown after etching under certain conditions and thus having a certain amount of undercutting determined by these conditions. The ridge created here under these conditions is referred to as ridge 4a. As shown, ridge 4a has a specified width A at the surface of layer 6, which width decreases towards the bottom due to undercutting. In the embodiment shown, the trenches 5 are formed up to a hidden insulating layer 7, which is provided, for example, in form of an oxide, so that the actual carrier material, e.g. silicon, or substrate 8 is electrically insulated from layer 6. The thickness of layer 6 and thus the depth of the trenches 5 amounts to some μm up to some ten μm, such as 30 μm to 60 μm. The amount of undercutting, which is indicated by 9a, is expressed by angle β1. Angle β1 indicates the deviation of the trench side wall in relation to perpendicular.

FIG. 3 shows a corresponding section, in case the etching has led to a greater amount of undercutting with otherwise identical design dimensions of the control structure 100. In this case, the etching has created a ridge 4b, the undercutting 9b of which is described by angle β2, which is substantially larger than angle β1. In the shown case, the greater undercutting also results in an undermining U. The region U represents an opening between the trenches 5, as ridge 4b is no longer connected to the hidden insulation layer 7 in this region.

It can be seen from FIGS. 2 and 3, how mobility of the control structure 100, in particular in form of the ridge 4b, is created by various undercuts, the ridge width A being constant.

The angles of undercutting 9a, β1, and 9b, β2, of trenches 5 of the control structure 100 determine whether the control structure 100 becomes moveable or not. If the trench depth is constant, the smaller angle of undercutting 9a, β1, (FIG. 2) corresponds to a lesser undercutting than that of the larger angle of undercutting 9b, β2 (FIG. 3). Thus, only the control structure having the larger angle of undercutting 9b, β2 (FIG. 3) becomes moveable. Ridge 4b is able to move laterally upon occurrence of stresses, which lateral movement, with high probability, results in a movement in the direction of arrow 10 (see FIG. 1) due to the small curvature 12 of ridge 4b in the embodiment shown.

In one embodiment, when operating the control structure 100, a gradually increasing current is supplied between the two contact surfaces 1 and 2 which results in a corresponding heating of the ridge 4 (4a, 4b) of the control structure 100. In the case in which the undercut regions at the trench bottom do not merge into each other (FIG. 2), ridge 4a of control structure 100 is still fixed mechanically to the hidden insulation layer 7 at the trench bottom, i.e. is immoveable. Because of the higher heat transmission due to the contact with the insulation layer 7, the increase in temperature of the ridge 4a is low. Thus, mechanical deflection of the ridge 4a is too low to contact the side wall of the surrounding semiconductor layer 6. In the case of an immoveable control structure 100, no current flow can be measured in the surrounding semiconductor material 6 by means of the contact surface 3. In the case of a moveable ridge 4b (FIG. 3), the ridge is no longer mechanically fixed to the trench bottom, since the undercut regions at the trench bottom merge into each other and form the undermining U. Because of the lower heat transmission, an increase in temperature is achieved such that the middle portion of the ridge is deflected in the direction of arrow 10 to such an extent that it contacts the side wall of the surrounding semiconductor material 6 in this place. In the case of a moveable control structure 100, a current flow can be measured in the surrounding semiconductor material 6 by means of the contact surface 3.

The procedure of determining a quantitative amount of undercutting which is graded within narrow limits is explained on the basis of FIGS. 4 to 6. For this purpose, a constant rate of undercutting is assumed, which is characterized by a constant angle of undercutting 9c, β3, wherein various ridge widths are provided.

FIG. 4 shows a control structure 100b comprising a ridge 4c of a width B after the etching process, wherein the undercutting 9c having the angle β3 has not yet eliminated the firm coupling of ridge 4c to the insulating layer 7.

FIG. 5 shows a control structure 100c comprising a ridge 4d of a width C after the etching process, wherein the ridge 4d just contacts the insulating layer 7 at the trench bottom.

FIG. 6 shows a control structure 100d comprising a ridge 4e of a width D after the etching process, wherein an undermining U has been formed and thus detachment of the ridge 4e has been obtained.

The plurality of control structures 100b, 100c, 100d having the various ridge widths A, B, C determines achievement of mobility of a corresponding ridge. Mobility is determined by the defined ridge width in the shown example of ridge 4e as well as of further ridges, if ridges having a ridge width smaller than D are provided. The control structure 100b of FIG. 4 having the defined large ridge width B remains immoveable, since the undercut regions at the trench bottom do not merge into each other. In FIG. 5, ridge 4d having the defined medium ridge width C is just moveable, since the undercut regions at the trench bottom just contact each other. Ridge 4e of control structure 100d of FIG. 6 having the defined small ridge width D is moveable (to a greater extent), when heated to a lesser degree than the ridge illustrated in FIG. 5, since the undercut regions at the trench bottom freely merge into each other. That means, when a specific measuring condition is provided, for example, by irradiation under defined conditions or supplying a defined current, a suitable value for defining undercutting 9c can be detected very precisely by means of the “switching action” caused by the lateral movement of a corresponding ridge, such as ridge 4e. Thus, when a plurality of control structures having variously defined ridge widths after etching is provided, a quantitative amount of undercutting can be determined on the basis of the measured mobility and knowledge of the defined ridge widths of all control structures.

In the embodiments described above, electric heating and electrical evaluation of mobility of the control structures are performed. In other embodiments, heating and/or detection of mobility may be accomplished by non-contact methods.

In one embodiment, control structures 100b, c, d are acted upon by suitable radiation, such as laser radiation, radiation of flash lamps, etc., wherein wavelength, intensity and/or duration of irradiation are adjusted appropriately in order to achieve a desired energy input into the corresponding control structures and the corresponding ridges, respectively. For example, when making contact with one of contact surfaces 1 or 2 and contact surface 3, a current flow can be detected upon irradiation if a ridge has a corresponding high mobility for making contact with the surrounding semiconductor material. Individual control structures may be measured simultaneously or serially, depending upon the possibilities of measurement. In case of a serial measurement, defined radiation pulses may be used so that identical conditions are provided for each measurement.

In other embodiments, mobility of the ridges is detected optically, wherein heating may be performed by radiation or electrically. For example, a control structure can be inspected optically during heating in order to thereby detect the quantity of the occurring movement. In the production of semiconductors, known devices, e.g. microscopes with downstream image processing, ellipsometers, and such like may be used for this purpose. In this way, a highly sensitive measurement of mobility is accomplished. In particular, in case of a heating of the control structures caused by radiation, all in all an efficient measuring method is achieved, since additional particle contamination caused by measuring can be kept very low.

In yet a further embodiment, the variable electrical behavior of ridges 4, 4a . . . , 4e is utilized which is caused by the various amounts of material removed. For example, the increasing resistance of ridges 4a, 4b may be determined and correlated with the various amounts of undercutting 9a, 9b. In this way, a change in etching parameters can be observed in a highly efficient manner. A very low current may be used in the corresponding measurement so that effects caused by said measurement, such as a change in conductivity upon change in temperature, are kept low. Thus, quantitatively precise measurements are achieved also in situations in which a perceptible change of mobility is not yet achieved, since an undermining U has not yet occurred.

Determination of electrical conductivity or resistance may also be combined with the methods for determining mobility described above so that, all in all, evaluation with respect to undercutting may be achieved over a wide range of etching conditions and ridge widths.

### List of Reference Numerals (Excerpt)

### FIG. 1

1: First contact surface of ridge of control structure
2: Second contact surface of ridge of control structure
3: Contact surface of surrounding silicon
4: Ridge of control structure
5: Trenches, 5A: trench structure
6: Surrounding silicon (active silicon layer)
10: Arrow indicating possible direction of movement
11: Length l (small L) of ridge in control structure
12: Radius r of curvature of ridge in control structure. R>>l

### FIG. 2

4a: Ridge of an immoveable control structure, which is still fixed to the hidden oxide
5: Trench
6: Surrounding silicon (active silicon layer)
7: Hidden oxide
8: Substrate wafer (handle wafer)
9a: Angle β1: Deviation of side wall from perpendicular determining the undercutting.

### FIG. 3

4b: Ridge of a moveable control structure, which is no longer fixed to the hidden oxide
5: Trench
6: Surrounding silicon (active silicon layer)
7: Hidden oxide
8: Substrate wafer (handle wafer)
9b: Angle β2: Deviation of side wall from perpendicular determining the undercutting.

### FIG. 4

4c: Ridge of an immoveable control structure, which is still fixed to the hidden oxide
5: Trench
6: Surrounding silicon (active silicon layer)
7: Hidden oxide
8: Substrate wafer (handle wafer)
9c: Angle β3: Deviation of side wall from perpendicular determining the undercutting.

### FIG. 5

4d: Remaining narrow ridge just contacting the bottom
5: Trench structure
6: Surrounding silicon (active silicon layer)
7: Hidden oxide
8: Substrate wafer (handle wafer)
9c: Angle β3: Deviation of side wall from perpendicular determining the undercutting.

### FIG. 6

4e: Ridge of a moveable control structure, which is no longer fixed to the hidden oxide
5: Trench
6: Surrounding silicon (active silicon layer)
7: Hidden oxide
8: Substrate wafer (handle wafer)
9c: Angle β3: Deviation of side wall from perpendicular determining the undercutting.

1. A method for evaluating an undercutting of deep trench structures in a semiconductor wafer wherein a control structure (100, 100b) is created on the semiconductor wafer, which control structure is configured such that as a result of a trench etching of a silicon layer of the semiconductor wafer, a silicon ridge (4b) is provided having a defined width between two adjacent trenches, the ridge being undermined (U) when undercuts merge into each other, wherein:
said silicon ridge is heated after the trench etching, said undermined ridge (4b) thereby caused to move as compared to a non-undermined silicon ridge; and
said movement is registered and serves as a criterion of a ridge mobility.

2. The method according to claim 1, wherein said silicon ridge is heated electrically.

3. The method according to claim 1, wherein said movement is registered electrically.

4. The method according to claim 1, wherein said silicon ridge is heated by radiation.

5. The method according to claim 1, wherein said silicon ridge is heated electrically and said movement is registered optically.

6. The method according to claim 1, wherein said silicon ridge is deflected until it contacts a trench wall, whereby an electrical contact is made, said contact then being registered.

7. The method according to claim 1, wherein control structures having variously defined stepped ridge widths are disposed on a semiconductor wafer and the amount of undercutting is determined after trench etching on the basis of registration of ridge movement and knowledge of the respective defined ridge width.

8. The method according to claim 4, wherein said said silicon ridge is heated by laser radiation.

9. The method according to claim 1, wherein adjacent trenches forming said ridge are configured such that a preferred lateral direction for a deflection of said ridge is obtained upon heating of said ridge.

10. The method according to claim 1, wherein said semiconductor wafer has a SOI structure having a hidden insulating layer and a semiconductor layer formed thereon.

11. The method according to claim 10, wherein said trench structure is formed down to the hidden insulating layer.

12. A method for evaluating an undercutting of a deep trench structure in a substrate suitable for the production of a micro-structure component, comprising:
producing a silicon ridge having a ridge width between two adjacent trenches by trench etching of a silicon layer of the substrate;
generating a current flow in said silicon ridge; and
assessing the amount of undercutting of said silicon ridge occurring during trench etching in a deeper region of the adjacent trenches using the generated current flow and a material loss of said ridge determined by the amount of undercutting.

13. The method according to claim 12, wherein generating the current flow comprises imprinting a suitable current for determining conductivity of said silicon ridge.

14. The method according to claim 12, wherein the current flow is generated in a suitable level for heating said silicon ridge, whereby said undermined ridge is caused to move in a clearly recognizable manner as compared to a non-undermined ridge due to expansion, said movement is registered and serves as a criterion of ridge mobility for assessing the amount of undercutting.

15. An arrangement for evaluating an undercutting of a deep trench structure in a semiconductor wafer comprising:
a component area for receiving micro-structure components, said area being defined by a trench structure (5A) having a given trench width;
a first control structure (100) having a structure different from that of said micro-structure components and a silicon ridge formed by two adjacent trenches (5) having a certain width and being partially open between said adjacent trenches, wherein said silicon ridge is fixed at both ends thereof and comprises a contact surface for contacting by an external test probe.

16. (canceled)

17. The arrangement according to claim 15, wherein a further contact surface formed in a semiconductor layer is provided which is electrically insulated from the contact surfaces of said silicon ridge.

18. The arrangement according to claim 15, wherein said silicon ridge has a curvature in order to define a preferred lateral direction upon thermal expansion of said silicon ridge.

19. The arrangement according to claim 15, wherein one or more further control structures having a ridge are provided, wherein said ridge of said one or more further control structures is formed by adjacent trenches having a defined trench width and has a ridge width differing from that of said silicon ridge of said first control structure.

20. The arrangement according to claim 15, wherein said adjacent trenches forming said silicon ridge of said first control structure extend in such a way that said first control structure is fully enclosed.

21. The arrangement according to claim 20, wherein said adjacent trenches extend down to a hidden insulation layer.

22. An arrangement for evaluating an undercutting of a structure of deep trenches in a SOI wafer comprising:
a component area defined by trenches having a defined width;
a plurality of control structures located outside said component area, each control structure comprising one respective silicon ridge formed by adjacent trenches having a defined width, and wherein silicon ridge widths at a surface are provided with values graded in a defined manner so that said silicon ridges have various amounts of undercutting due to trench etching and thus various amounts of lateral mobility, wherein at least one contact surface for making contact with an external probe is provided in each control structure, said contact surface being connected with a respective silicon ridge.

23. The arrangement according to claim 22, wherein each silicon ridge has a curvature so that a preferred lateral direction is defined upon thermal expansion of said silicon ridges.

24. The arrangement according to claim 23, wherein said curvature has a radius of curvature being greater than a length of an associated silicon ridge.

25. (canceled)

26. An arrangement in the form of a control structure for evaluating an undercutting of a deep trench structure in a SOI wafer, configured such that a silicon ridge having a defined ridge width is formed between two adjacent trenches extending substantially in parallel with each other in a portion of said arrangement as a result of trench etching, said silicon ridge is undermined when undercuts merge into each other and regions are formed in two portions adjacent to the ends of said silicon ridge which are not completely undermined during etching;
wherein said trench comprises a closed trench, which encloses all three portions of said control structure;
wherein contact points are provided in non-undermined portions at ends of said silicon ridge and in an adjacent non-etched semiconductor area for electric heating of said silicon ridge and for measuring a deflection thereof due to heating.

27. The arrangement according to claim 26, wherein said silicon ridge has a curvature to be described by a specific radius of curvature in order to define an unambiguous direction of deflection of said silicon ridge upon heating.

28. The arrangement according to claim 26, wherein the arrangement is configured such that a number of ridges of various widths are provided.

29. A method for evaluating an undercutting of deep trench structures in SOI wafers using a control structure created on said SOI wafers, which control structure is configured such that a silicon ridge having a defined ridge width is formed between two adjacent trenches extending in parallel with each other as a result of trench etching, which silicon ridge is undermined when undercuts merge into each other, wherein said silicon ridge is heated after trench etching, whereby said undermined silicon ridge is caused to move in comparison to a non-undermined ridge, due to expansion, said movement being registered and serving as a criterion of mobility for evaluating an amount of undercutting.

30. The method according to claim 29, wherein said silicon ridge is heated electrically and said movement is registered electrically.

31. The method according to claim 1, wherein said movement is for evaluating and assessing an amount of undercutting.

32. The method according to claim 1, wherein said movement is registered optically.

33. The method according to claim 2, wherein said movement is registered electrically.
